(19) United States
(12) Patent Application Publication
(10) Pub. No.: US 2005/0000453 A1
(43) Pub. Date: Jan. 6, 2005

(54) Apparatus for semiconductor device and method using the same

(76) Inventors: Chul-Ju Hwang, Gyeonggi-do (KR); Sang-Gon Lee, Gyeonggi-do (KR)

Correspondence Address: MARGER JOHNSON & McCOLLOM, P.C., 1030 S.W. Morrison Street, Portland, OR, 97205, US

(21) Appl. No.: 10/860,534

(22) Filed: Jun. 2, 2004

(30) Foreign Application Priority Data
Jun. 2, 2003 (KR) 2003-35384

(51) Int. Cl. C23C 16/00

(52) U.S. Cl. 118/728

(57) ABSTRACT

An apparatus for a semiconductor device includes: a chamber; a susceptor in the chamber; a plurality of heating-blocks on the susceptor; a lift pin assembly through the susceptor; a substrate holder over the susceptor, the substrate holder having a plurality of through holes corresponding to the plurality of heating-blocks; and a shaft combined with the substrate holder-through the susceptor.

The present invention claims the benefit of Korean Patent Application No. 2003-35384 filed in Korea on Jun. 2, 2003, which is hereby incorporated by reference.

### BACKGROUND OF THE INVENTION

1. Field of the Invention

The present invention relates to an apparatus for a semiconductor device, and more particularly, to an apparatus where a plurality of substrates are loaded on a susceptor at the same time and a method using the same.

2. Discussion of the Related Art

In general, a semiconductor device includes a pattern of multiple layers on a substrate and the pattern on the substrate is obtained through a process in a chamber under an optimum condition. In order to increase throughput, the process in a chamber may be performed for a plurality of substrates and the chamber may include a plurality of heating-blocks that the plurality of substrates are loaded on. In conventional loading and heating steps, the plurality of substrates are sequentially carried into the chamber and are sequentially loaded on the plurality of heating-blocks one by one. Each heating-block including a heater is heated before the substrate is loaded for preheating. Accordingly, the plurality of substrates have different preheating times, thereby having different temperatures during the process. As a result, the plurality of substrates having different process conditions and production yield decreases.

### SUMMARY OF THE INVENTION

Accordingly, the present invention is directed to an apparatus for a semiconductor device that substantially obviates one or more of the problems due to limitations and disadvantages of the related art.

An object of the present invention is to provide an apparatus where a plurality of substrates are preheated equally and a method using the apparatus.

Another object of the present invention is to provide an apparatus having improved production yield without reduction of property uniformity of a plurality of substrates and a method using the apparatus.

Another object of the present invention is to provide a loading unit of an apparatus for a semiconductor device where a plurality of substrates are loaded on a plurality of heating-blocks simultaneously and a method of loading a plurality of substrates.

Additional features and advantages of the invention will be set forth in the description which follows, and in part will be apparent from the description, or may be learned by practice of the invention. The objectives and other advantages of the invention will be realized and attained by the structure particularly pointed out in the written description and claims hereof as well as the appended drawings.

To achieve these and other advantages and in accordance with the purpose of the present invention, as embodied and broadly described, an apparatus for a semiconductor device includes: a chamber; a susceptor in the chamber; a plurality of heating-blocks on the susceptor; a lift pin assembly through the susceptor; a substrate holder over the susceptor, the substrate holder having a plurality of through holes corresponding to the plurality of heating-blocks; and a shaft combined with the substrate holder through the susceptor.

In another aspect, a method of loading a plurality of substrates in an apparatus for a semiconductor device includes: loading one of the plurality of substrates on one of a plurality of through holes of a substrate holder in a chamber; loading the others of the plurality of substrates on the others of the plurality of through holes by repeating the step of loading one of the plurality of substrates; and loading the plurality of substrates on a plurality of heating-blocks under the substrate holder simultaneously.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the invention and together with the description serve to explain the principles of the invention. In the drawings:

FIG. 1 is an exploded perspective view showing a loading unit of an apparatus for a semiconductor device according to an embodiment of the present invention; and

FIGS. 2A to 2I are perspective views illustrating a method of loading a plurality of substrates in an apparatus according to an embodiment of the present invention.

### DETAILED DESCRIPTION OF THE PREFERRED EMBODIMENTS

Reference will now be made in detail to the preferred embodiments, examples of which are illustrated in the accompanying drawings.

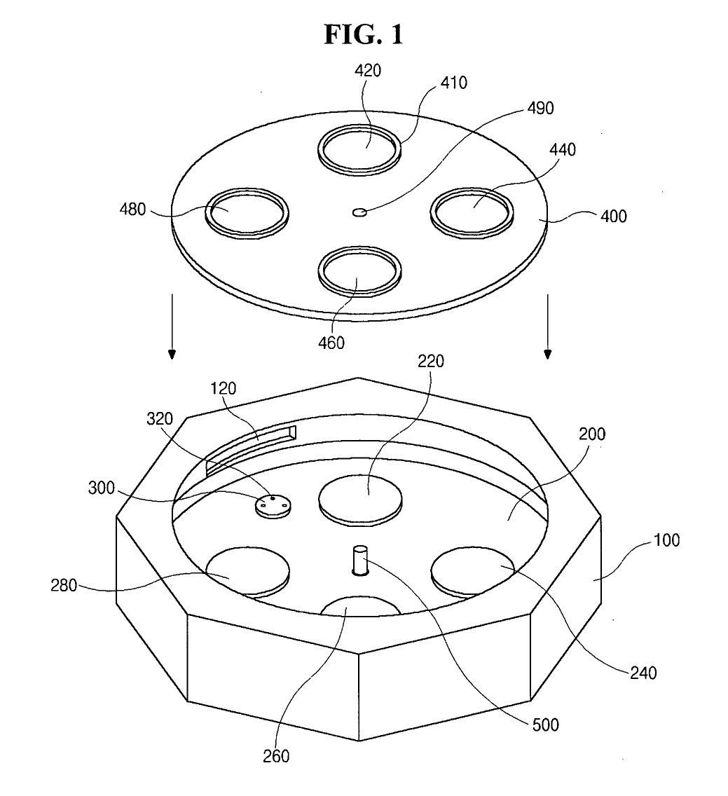

FIG. 1 is an exploded perspective view showing a loading unit of an apparatus for a semiconductor device according to an embodiment of the present invention.

In FIG. 1, a loading unit of an apparatus for a semiconductor device includes a chamber 100, a susceptor 200 and a substrate holder 400. The chamber 100 having a gate 120 for a substrate provides a reactive space for a process and the gate 120 may be formed through a sidewall of the chamber 100. The chamber 100 may be encapsulated with a lid assembly (not shown) using a sealing means such as an o-ring. The susceptor 200 is disposed in the chamber 100 and a plurality of heating-blocks 220, 240, 260 and 280 are formed on the susceptor 200. The plurality of heating-blocks 220, 240, 260 and 280 preheat a substrate thereon and may perpendicularly protrude from the susceptor 200. In addition, a lift pin assembly 300 and a shaft 500 are formed through the susceptor 200. The lift pin assembly 300 includes a lift pin 320 therein for up-and-down movement of the substrate. Moreover, the lift pin assembly 300 may face the gate 120 and be disposed between the heating-blocks 220 and 240 adjacent to the gate 120.

The substrate holder 400 is disposed over the susceptor 200 and includes a plurality of through holes 420, 440, 460 and 480 corresponding to the plurality of heating-blocks 220, 240, 260 and 280. The substrate holder 400 further includes an axis hole 490 at a central portion. The substrate holder 400 is combined with the shaft 500 by interposing an upper end of the shaft 500 through a central hole 490. The shaft 500 may be fixed to the substrate holder 400 using a fixing means (not shown). Thus, the substrate holder 400 may move up and down or rotate according to the movement of the shaft 500. In addition, an auxiliary holder 410 of a ring shape may be formed in each through hole of the substrate holder 400 for holding the substrate more safely. Each through hole may have an area greater than an area of a top surface of each heating-block. Although four through holes and four heating-blocks are shown in FIG. 1, the number of the through holes and the corresponding heating-blocks may be variously changed in another embodiment.

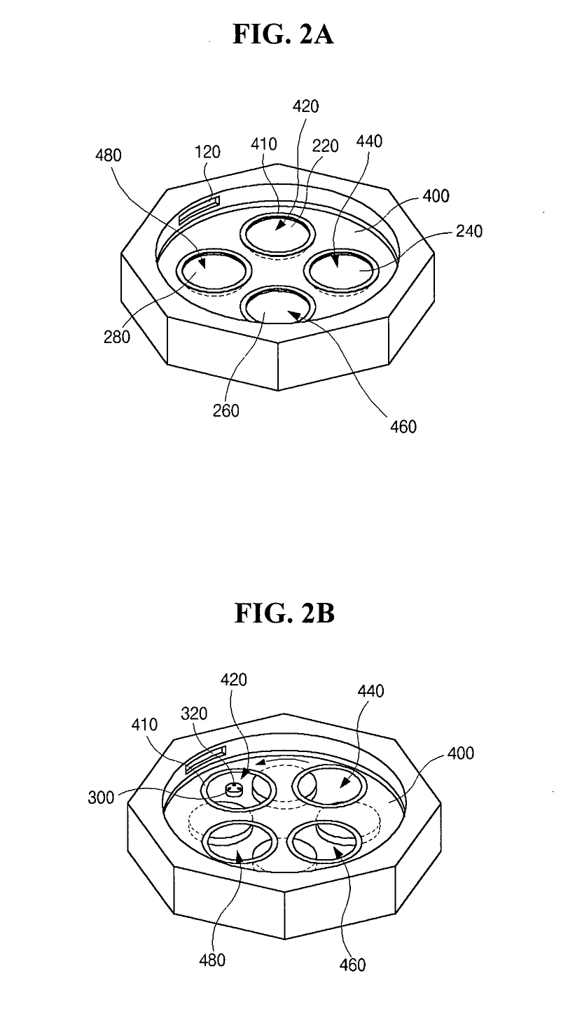

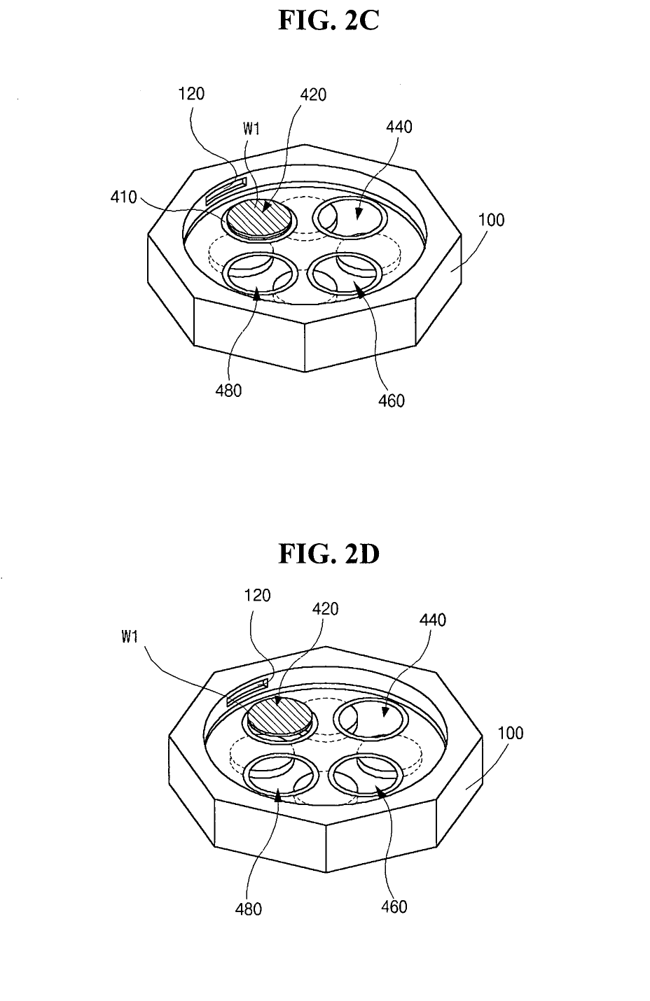

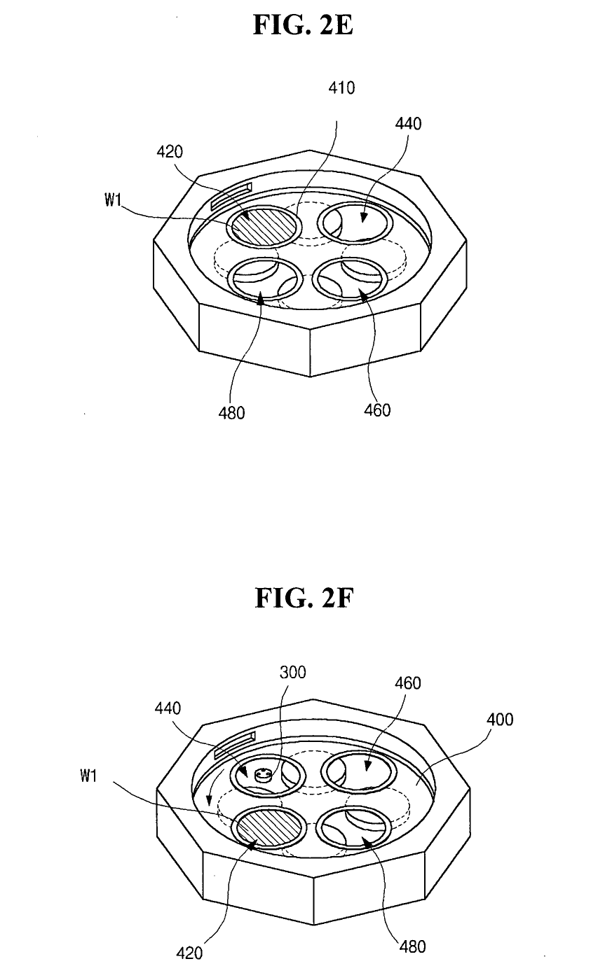

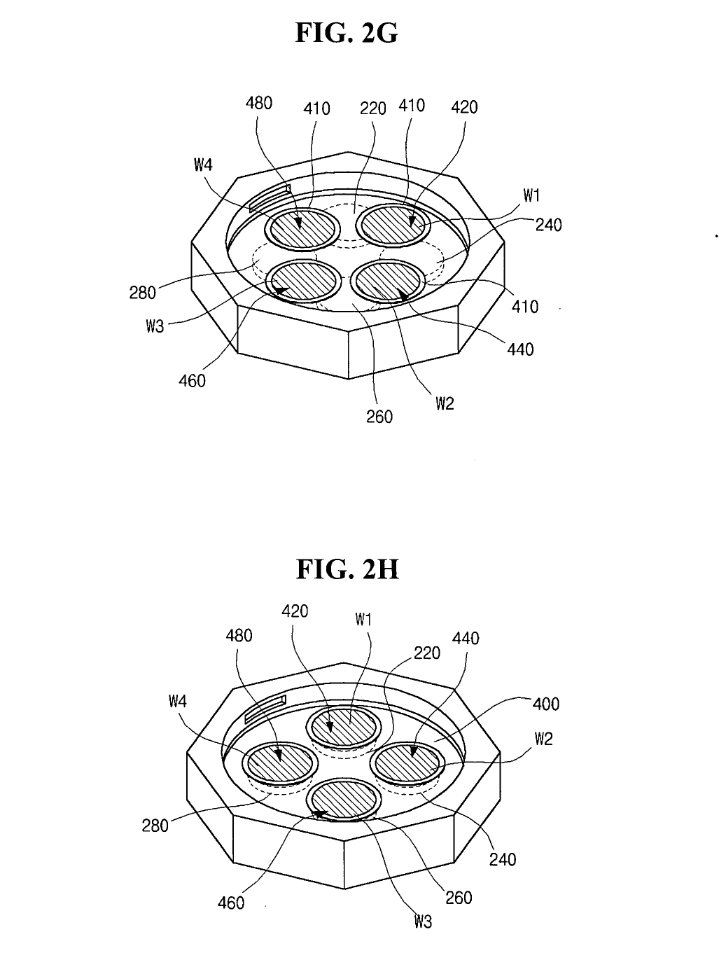

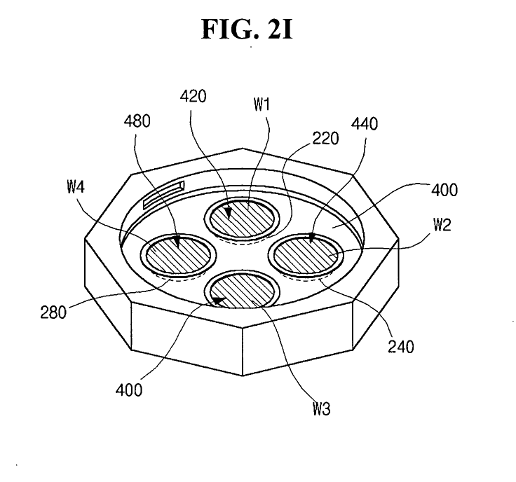

FIGS. 2A to 2I are perspective views illustrating a method of loading a plurality of substrates in an apparatus according to an embodiment of the present invention.

In FIG. 2A, a substrate holder 400 includes first, second, third and fourth through holes 420, 440, 460 and 480, and first, second, third and fourth heating-blocks 220, 240, 260 and 280 are formed on a susceptor 200 (of FIG. 1). An auxiliary holder 410 is disposed in each through hole 420, 440, 460 and 480 of the substrate holder 400. For example, before a substrate is loaded, the substrate holder 400 may be disposed such that a center of each through hole 420, 440, 460 and 480 coincides with a center of each heating-blocks 220, 240, 260 and 280.

In FIG. 2B, the substrate holder 400 moves up and down and rotates according to movement and rotation of a shaft 500 (of FIG. 1) such that each through hole 420, 440, 460 and 480 of the substrate holder 400 is positioned between adjacent heating-blocks 220, 240, 260 and 280. Thus, a lift pin assembly 300 is disposed to coincide with a center of the first through hole 420.

In FIG. 2C, a first substrate “W1” may be carried into a chamber 100 through a gate 120 by a delivering means (not shown) such as a robot arm. The first substrate “W1” is disposed over the first through hole 420.

In FIG. 2D, after the first substrate “W1” is disposed over the first through hole 420, a lift pin 320 of the lift pin assembly 300 under the first through hole 420 moves up and supports the first substrate “W1.” After the lift pin 320 supports the first substrate “W1,” the delivering means may be extracted from the chamber 100 and then the gate 120 may be closed.

In FIG. 2E, the lift pin 320 of the lift pin assembly 300 moves down and then the auxiliary holder 410 in the first through hole 420 supports the first substrate “W1.”

In FIG. 2F, the substrate holder 400 rotates according to rotation of the shaft 500 (of FIG. 1) such that the lift pin assembly 300 coincides with a center of the second through hole 440.

In FIG. 2G, second, third and fourth substrates “W2,” “W3” and “W4” are loaded on auxiliary holders 410 in the second, third and fourth through holes 440, 460 and 480 by repeating similar loading steps.

In FIG. 2H, the substrate holder 400 rotates according to rotation of the shaft 500 (of FIG. 1), thereby the first, second, third and fourth through holes 420, 440, 460 and 480 corresponding to the first, second, third and fourth heating blocks 220, 240, 260 and 280, respectively, as in FIG. 2A.

In FIG. 21, after the substrate holder 400 is disposed such that a center of each through hole 420, 440, 460 and 480 coincides with a center of each heating-blocks 220, 240, 260 and 280, the substrate holder 400 moves down according to movement of the shaft 500 (of FIG. 1). Thus, the first, second, third and fourth substrates “W1,” “W2,” “W3” and “W4” are simultaneously loaded on the first, second, third and fourth heating-blocks 220, 240, 260 and 280, respectively. After loading the first, second, third and fourth substrates “W1,” “W2,” “W3” and “W4,” a process such as deposition of thin film may be performed.

Since the first, second, third and fourth substrates “W1,” “W2,” “W3” and “W4” are simultaneously loaded, the first, second, third and fourth substrates “W1,” “W2,” “W3” and “W4” are heated for the same preheating time and have the same substrate temperature. In other words, the first, second, third and fourth substrates “W1,” “W2,” “W3” and “W4” have the same initial process condition. Accordingly, a uniformity in property is improved and production yield increases.

Although the auxiliary holder 410 is used in the embodiment of FIGS. 2A to 2I, the auxiliary holder 410 may not be used and the substrate may be loaded on a boundary portion of each through hole without the auxiliary holder 410 in another embodiment. Furthermore, the substrate holder 400 rotates by about 45° or about 90° in FIGS. 2A to 2I. The rotation angle of the substrate holder 400 depends on the number of the through holes and the corresponding heating-blocks. Accordingly, the rotation angle and the number of the through holes and the corresponding heating-blocks may be variously changed in another embodiment.

In the present invention, after a plurality of substrate are loaded on a substrate holder, the plurality of substrates are simultaneously loaded on a plurality of heating-blocks. Accordingly, the plurality of substrates are heated for the same preheating time, thereby having substantially the same substrate temperature. Therefore, a uniformity in property of a subsequent process is improved and production yield increases.

It will be apparent to those skilled in the art that various modifications and variations can be made in the apparatus for a semiconductor device without departing from the spirit or scope of the invention. Thus, it is intended that the present invention covers the modifications and variations of this invention provided they come within the scope of the appended claims and their equivalents.

1. An apparatus for a semiconductor device, comprising:
a chamber;
a susceptor in the chamber;
a plurality of heating-blocks on the susceptor;
a lift pin assembly through the susceptor;
a substrate holder over the susceptor, the substrate holder having a plurality of through holes corresponding to the plurality of heating-blocks; and
a shaft combined with the substrate holder through the susceptor.

2. The apparatus according to claim 1, wherein the chamber has a gate through a sidewall thereof for carrying a substrate.

3. The apparatus according to claim 2, wherein the lift pin assembly is disposed on a line connecting the gate and the shaft between the adjacent heating-blocks.

4. The apparatus according to claim 1, wherein the shaft performs up-and-down movement and rotation.

5. The apparatus according to claim 4, wherein the substrate holder moves up and down and rotates according to the up-and-down movement and rotation of the shaft.

6. The apparatus according to claim 1, further comprising an auxiliary holder in each through hole.

7. The apparatus according to claim 1, wherein each through hole has an area greater than an area of a top surface of each heating-block.

8. The apparatus according to claim 1, wherein the susceptor has a disc shape and the plurality of through holes have a circular shape.

9. The apparatus according to claim 8, wherein the plurality of through holes are symmetrically disposed with respect to a center of the susceptor.

10. The apparatus according to claim 9, wherein the lift pin assembly is disposed on a circumference of a circle connecting centers of the plurality of through holes.

11. A method of loading a plurality of substrates in an apparatus for a semiconductor device, comprising:
loading one of the plurality of substrates on one of a plurality of through holes of a substrate holder in a chamber;
loading the others of the plurality of substrates on the others of the plurality of through holes by repeating the step of loading one of the plurality of substrates; and
loading the plurality of substrates on a plurality of heating-blocks under the substrate holder simultaneously.

12. The method according to claim 11, wherein the step of loading one of the plurality of substrates comprises:
rotating the substrate holder such that the one of the plurality of through holes corresponds to a lift pin assembly between the adjacent heating-blocks;
carrying the one of the plurality of substrates into the chamber through a gate on a sidewall of the chamber to be disposed over the one of the plurality of through holes;
moving up the lift pin assembly to support the one of the plurality of substrates; and
moving down the lift pin assembly to load the one of the plurality of substrates on the one of a plurality of through holes.

13. The method according to claim 12, wherein the step of rotating the substrate holder includes rotating a shaft connected to the substrate holder.

14. The method according to claim 12, further comprising rotating the substrate holder such that the other one of the plurality of through holes corresponds to the lift pin assembly after the step of loading one of the plurality of substrates.

15. The method according to claim 1, wherein the step of loading the plurality of substrates includes moving down the substrate holder such that the plurality of substrates contact the plurality of heating-blocks.

16. The method according to claim 15, wherein the step of moving down the substrate holder includes moving down a shaft connected to the substrate holder.
